(19) United States
(12) Patent Application Publication
(10) Pub. No.: US 2015/0074359 A1
(43) Pub. Date: Mar. 12, 2015

(54) ELECTRONIC APPARATUS, CONTROL METHOD THEREFOR, AND COMPUTER PROGRAM PRODUCT

(71) Applicant: Yuuki SUNAGAWA, Kanagawa (JP)

(72) Inventor: Yuuki SUNAGAWA, Kanagawa (JP)

(73) Assignee: RICOH COMPANY, LIMITED, Tokyo (JP)

(21) Appl. No.: 14/477,952

(22) Filed: Sep. 5, 2014

(30) Foreign Application Priority Data
Sep. 9, 2013 (JP) 2013-186675
Jul. 17, 2014 (JP) 2014-146800

(51) Int. Cl. G06F 13/18; G11C 14/00

(52) U.S. Cl. CPC G06F 13/18; G11C 14/0045; G11C 13/0002
USPC 711/158

(57) ABSTRACT

An electronic apparatus includes: a main storage unit; a first storage unit that stores multiple pieces of first setting information for the main storage unit; a second storage unit that stores second setting information, the second setting information being setting information for the main storage unit and corresponding to at least some of the multiple pieces of first setting information; a setting unit that sets the second setting information with a higher priority than the first setting information; and a control unit that controls the main storage unit based on information set by the setting unit.

### CROSS-REFERENCE TO RELATED APPLICATIONS

The present application claims priority to and incorporates by reference the entire contents of Japanese Patent Application No. 2013-186675 filed in Japan on Sep. 9, 2013 and Japanese Patent Application No. 2014-146800 filed in Japan on Jul. 17, 2014.

### BACKGROUND OF THE INVENTION

1. Field of the Invention

The present invention relates to an electronic apparatus, a control method, and a computer program product.

2. Description of the Related Art

General electronic apparatuses including image processing apparatuses (e.g., personal computers) and image forming apparatuses (e.g., multifunction peripherals) typically employ a configuration in which a memory module including a memory such as a DRAM (dynamic random access memory) and implemented in a PCB (printed circuits board) is connected to a CPU (central processing unit) or an ASIC (application specific integrated circuit). Each time the memory in such a memory module is changed, the memory is initialized so that the memory can operate properly.

Memory initialization is generally performed by a BIOS (basic input output system), which is a configuration program, by reading access parameters from a flash ROM based on a default specification information (hereinafter, referred to as “SPD information”) of SPD (Serial Presence Detect) for the mounted memory, such as row address size and column address size, and setting the access parameters to the memory controller. The SPD is a standard defined by the JEDEC (Joint Electron Device Engineering Council).

In a built-in type system including an SPDROM (serial presence detect read only memory) for a main memory in a case where handling is impossible with pre-stored default access parameters read out by BIOS due to upgrading of the memory or the like, access parameters after the upgrading of the main memory are read out from the SPD ROM and set to a memory controller (see paragraph [0002] of Japanese Laid-open Patent Application No. 2009-110429).

Meanwhile, because DRAMs are devices which undergo die shrink (reduction in semiconductor chip size) in short cycles, change in characteristics of the DRAM from development phase may occur with time. Therefore, the conventional method of reading out the access parameters after the upgrading from the SPD ROM for the main memory, and setting the readout access parameters to the memory controller can cause a problem such as a failure to startup or an unexpected operation due to the occurrence of degradation in quality of waveform or timing.

When, for example, it is demanded to change a current vendor of DRAMs to another vendor because of production cease of the DRAMs or for cost reason, it is necessary to change BIOS in a flash ROM where DRAM setting information (hereinafter, sometimes referred to as “setting values”) is recorded. Changing settings of both the memory and software (i.e., the BIOS) simultaneously is not necessarily easy. This is because, for example, production site of a CTL (controller) board of a DIMM (dual inline memory module) used as the memory module differs from that of the memory (DRAM) mounted on the memory module.

Under the circumstances, there is a need to make it possible to set setting optimum for a mounted main memory.

### SUMMARY OF THE INVENTION

It is an object of the present invention to at least partially solve the problems in the conventional technology.

An electronic apparatus includes: a main storage unit; a first storage unit that stores multiple pieces of first setting information for the main storage unit; a second storage unit that stores second setting information, the second setting information being setting information for the main storage unit and corresponding to at least some of the multiple pieces of first setting information; a setting unit that sets the second setting information with a higher priority than the first setting information; and a control unit that controls the main storage unit based on information set by the setting unit.

A control method is to be performed by an electronic apparatus including a main storage unit, a first storage unit that stores multiple pieces of first setting information for the main storage unit, and a second storage unit that stores second setting information, the second setting information being setting information for the main storage unit and corresponding to at least some of the multiple pieces of first setting information. The control method includes: setting the second setting information with a higher priority than the first setting information; and controlling the main storage unit based on the information set at the setting.

A computer program product includes a non-transitory computer-readable medium containing an information processing program. The program, when executed by a computer including a main storage unit, a first storage unit that stores multi pieces of first setting information for the main storage unit, and a second storage unit that stores second setting information, the second setting information being setting information for the main storage unit and corresponding to at least some of the multiple pieces of first setting information, causes the computer to function as: a setting unit that sets the second setting information with a higher priority than the first setting information; and a control unit that controls the main storage unit based on the information set by the setting unit.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a diagram illustrating a basic structure of an electronic apparatus (memory system) according to an embodiment;

FIG. 2 is a functional block diagram illustrating an example functional structure of the electronic apparatus (memory system) according to the embodiment;

FIG. 3 is an explanatory diagram of a basic concept of control for setting the setting values to a memory controller according to a conventional method;

FIG. 4 is an explanatory diagram of a basic concept of control for setting the setting values to a memory controller according to the embodiment;

FIG. 5 is an explanatory diagram of an example structure of a DRAM CTL register of the memory controller;

FIG. 6 is a diagram describing difference in setting values between the conventional setting method and the setting method according to the embodiment;

FIG. 7 is a flowchart illustrating an example sequence of operations for setting the setting values to a main memory according to the embodiment;

FIG. 8 is a flowchart illustrating another example sequence of operations for setting the setting values to the main memory according to the embodiment;

FIG. 9 is a diagram illustrating a basic structure of an electronic apparatus (memory system) according to a modification of the embodiment; and

FIG. 10 is a functional block diagram illustrating an example functional structure of the electronic apparatus (memory system) according to the modification.

### DETAILED DESCRIPTION OF THE PREFERRED EMBODIMENTS

An electronic apparatus according to an embodiment, at the time of initialization control of, for example, a DRAM (main storage unit) mounted on a main memory, reads out setting values (access parameters) of a mounted DRAM (main storage unit) from a storage unit (second storage unit) other than a storage unit (first storage unit) where default setting values of the DRAM are stored. For example, even if a DRAM which has undergone die shrink multiple times and therefore has characteristics considerably different from a development phase or, in short, even if the specification of the DRAM is changed, setting values (access parameters) of the mounted DRAM are read out from an SPD memory (corresponding to the second storage unit) where specification information of the DRAM is recorded. Accordingly, optimum settings for the mounted main memory can be set to the main memory.

Exemplary embodiments are described below with reference to the accompanying drawings.

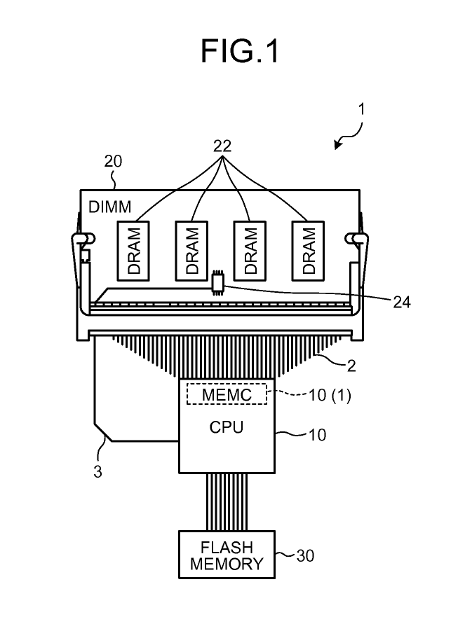

FIG. 1 is a diagram illustrating a basic structure of a memory system for initializing a main memory after the specification change according to an embodiment. The memory system is an example of the electronic apparatus. The electronic apparatus may be any apparatus including a memory system. For example, the electronic apparatus (memory system) according to the embodiment may be implemented in a general personal computer.

A memory system 1 according to the embodiment includes a CPU 10, a DIM 20 (memory module), and a flash memory 30 (first storage unit) as illustrated in FIG. 1. The CPU 10 includes a memory controller 10(1) (control unit, MEMC). Any one or more or all of functions of the CPU 10 may be implemented in an ASIC. The DIMM 20 and the flash memory 30 are respectively connected to the CPU 10. The DIMM 20 may be connected to the CPU 10 via, for example, a DRAM bus 2 and an I²C bus 3. The DIMM 20 includes one or more DRAMs (hereinafter, “DRAM”) 22 (main storage unit) and an SPD memory 24 (second storage unit, SPD storage unit). The flash memory 30 stores setting values of the DRAM 22 and BIOS, which is a configuration program. The SPD memory 24 stores specification information and setting values of the DRAM 22.

Note that the structure of the memory system 1 is not limited to that illustrated in FIG. 1. For example, the memory module may be implemented as an on-board component of a mother board or the like. The second storage unit may be implemented in another non-volatile memory rather than in a part or all of the SPD memory 24.

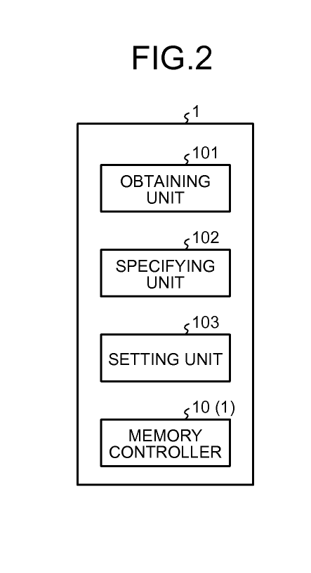

FIG. 2 is a functional block diagram illustrating an example functional structure of the electronic apparatus (memory system) according to the embodiment. As illustrated in FIG. 2, the memory system 1 includes, as primary functional components, an obtaining unit 101, a specifying unit 102, a setting unit 103, and the memory controller 10(1).

The obtaining unit 101 obtains (reads) various types of information from storage units including the flash memory 30 and the SPD memory 24. For example, the obtaining unit 101 obtains SPD information from the SPD memory 24. The function of reading access parameters or like information from the flash memory 30 may be implemented in the BIOS.

The specifying unit 102 specifies a setting target to be applied from one or more setting targets based on SPD information, for example. The setting target is information which defines a set of setting values to be set to the memory controller 10(1). Hereinafter, an example where two setting targets, which are a setting A and a setting B, are provided is described. However, the number of the setting targets is not limited to two; the number may alternatively be one, or three or more. The specifying unit 102 specifies the setting target, which is one of the settings A and B, corresponding to specification provided by the SPD information, for example.

The setting unit 103 initializes the memory controller 10(1) by setting the setting values to the memory controller 10(1)). At this time, the setting unit 103 sets the setting values (second setting information) stored in the SPD memory 24 with a higher priority than setting values (first setting information) defined the specified setting target. The detail of the setting operation by the setting unit 103 will be described later.

The memory controller 10(1) controls operations of the DRAM 22 based on the set setting values.

The units illustrated in FIG. 2 may be implemented by, for example, causing the CPU 10 to execute programs or, in short, in software, implemented in hardware circuitry such as an ASIC, or implemented in a combination of software and hardware circuitry. An example where the units illustrated in FIG. 2 are implemented by causing the CPU 10 to execute programs is described below.

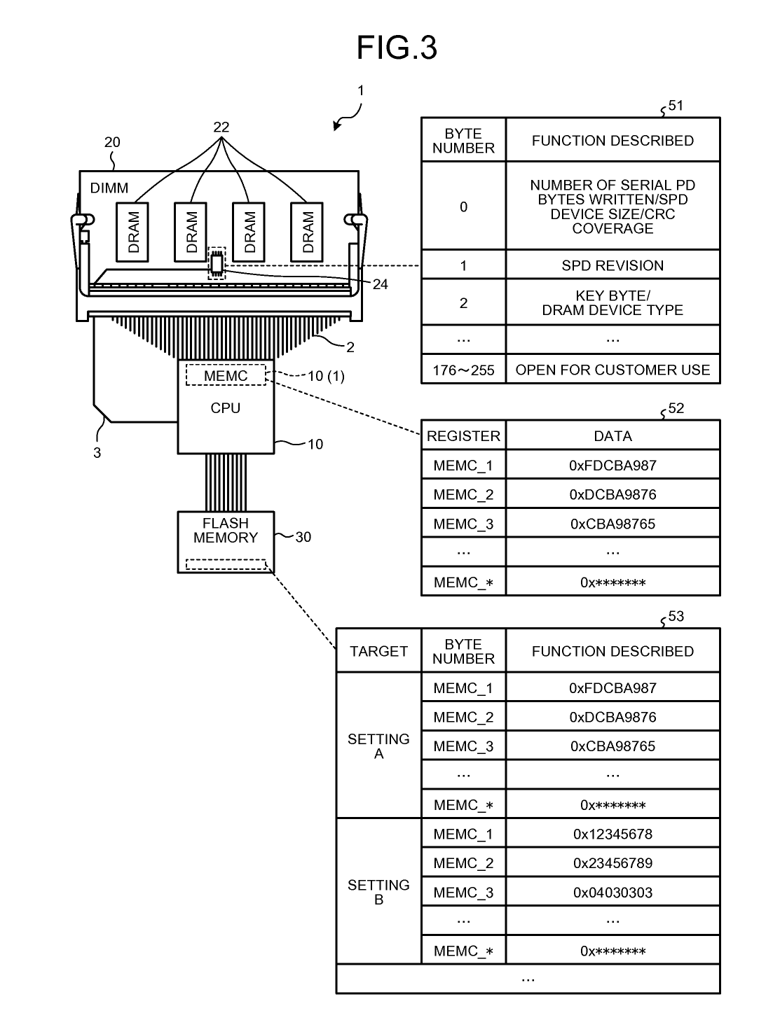

FIG. 3 is an explanatory diagram of a basic concept of control for setting the setting values to a memory controller for initialization of the main memory after the specification change (the DRAM 22) according to a conventional method for comparison with a method according to the embodiment.

Data 51 (JEDEC-defined SPD information which is specification information of the DRAM 22) indicated on the right side of FIG. 3 is recorded in a memory device, which is the SPD memory 24 in this example. The data 51 contains byte numbers and functions described for each of the byte numbers. For example, the number of serial PD bytes written, an SPD device size, and a CRC (cyclical redundancy code) coverage are recorded in Byte 0 of the data 51. SPD revision, which is information about an SPD revision, is recorded in Byte 1. A key byte and a DRAM device type are recorded in Byte 2. Bytes 176 to 255 are open for customer use.

Data 52 is data stored in DRAM CTL registers in the memory controller 10(1) in the CPU 10. Setting value data placed in registers MEMC_1 to MEMC_* (hereinafter, sometimes simply referred to as “MEMC_1 to MEMC_*”), respectively, is recorded in the data 52.

Data 53 is data stored in DRAM registers in the flash memory 30. The setting A and the setting B are recorded in the data 53 as the setting targets. Each of the settings A and B contains the setting values listed in FIG. 3.

In the configuration described above, the obtaining unit 101 reads data (SPD information) from the SPD memory 24. This data contains specification information including, for example, capacities, bus widths, and the numbers of ranks of the DRAM 22. The specifying unit 102 determines which setting values are to be used for setting among the setting targets (in the example illustrated in FIG. 3, the setting A or B) stored in the DRAM registers in the flash memory 30 based on the specification information. The obtaining unit 101 reads the setting values (access parameters) of the thus-determined one of the setting A and the setting B from the flash memory 30. The setting unit 103 sets the readout setting values to the memory controller 10(1). More specifically, the setting unit 103 places the values in the registers (the DRAM CTL registers) of the memory controller 10(1). It is assumed in this example that the setting values of the setting A stored in the flash memory 30 are set.

The method described above can specify a more appropriate one of the two setting targets in accordance with specification of the DRAM 22 and set setting values defined in the specified setting target. However, the setting values defined in each of the setting targets are limited to setting values defined by the SPD specification, for example. Therefore, setting values which are not defined by the SPD specification, for example, cannot be assigned. Furthermore, fixed setting values that depend on a specific specification are defined in each of the setting targets. Accordingly, it is not possible to modify only one or more of multiple setting values defined in a setting target, for example. Therefore, there is a possibility that optimum settings for a mounted main memory cannot be set to the main memory.

A basic concept of control for setting the setting values to the memory controller 10(1) for initialization of the main memory (the DRAM 22 in the DIMM 20) according to the embodiment is described below.

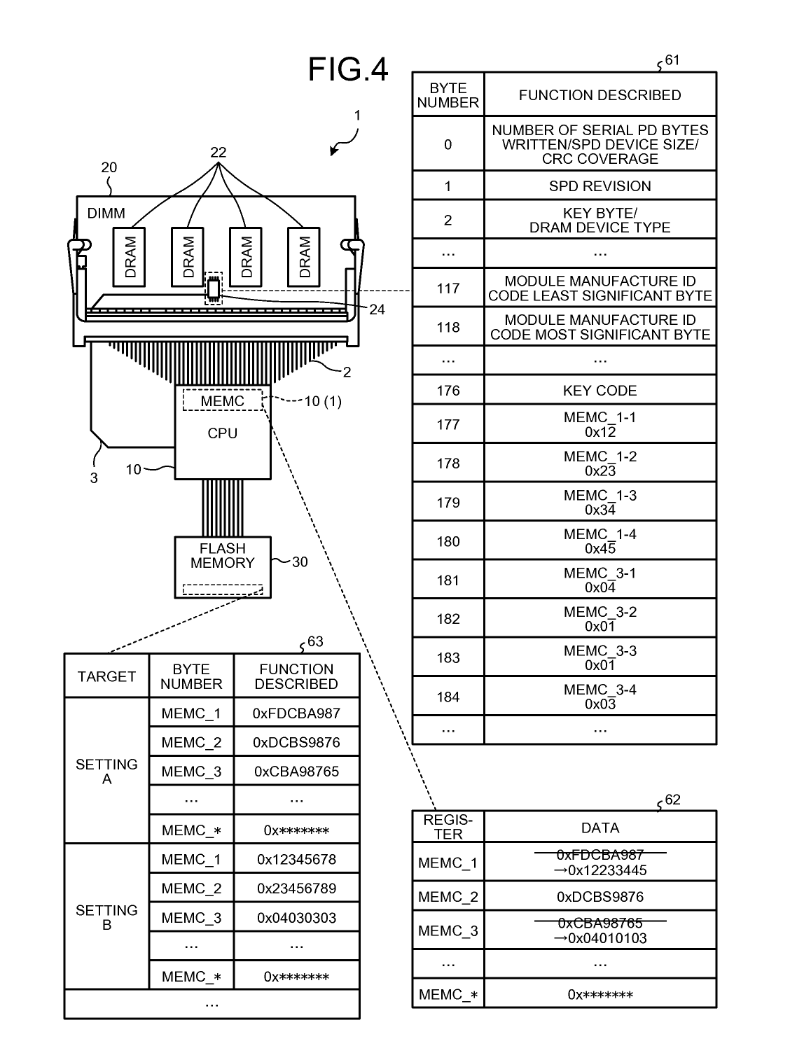

FIG. 4 is an explanatory diagram of the basic concept of control for setting the setting values to the memory controller 10(1) for initialization of the main memory after the specification change (the DRAM 22 in the DIMM 20 manufactured by the own company) according to the embodiment.

The registers or, more specifically, the data registers in the SPD memory 24, the DRAM CTL registers in the memory controller 10(1), and the DRAM registers in the flash memory 30, are identical to those illustrated in FIG. 3. However, data stored in each of the registers differs from that illustrated in FIG. 3. For example, data 61 is stored in the data registers in the SPD memory 24. Data 62 is stored in the DRAM CTL registers in the memory controller 10(1). Data 63 is stored in the DRAM registers in the flash memory 30. Module manufacturing ID codes are stored in Bytes 117 and 118 of the data 61. A key code indicating that the DIMM 20 is manufactured by the own company and setting values are stored in Bytes 176 to 255 which are open for customer use. Examples of the setting values stored in Bytes 176 to 255 which are open include access parameters not defined by the JEDEC (hereinafter, “JEDEC-non-defined access parameters”).

More specifically, the access parameters according to the embodiment include conventionally-employed access parameters which are based on the SPD information defined by the JEDFEC (hereinafter, referred to as “JEDEC-defined access parameters” for distinction from “JEDEC-non-defined access parameters”) and the JEDEC-non-defined access parameters. In the example illustrated in FIG. 4, one set is made up of four data pieces of the MEMC_1-1 to MEMC_1-4 (8 bits each). The one set corresponds to a single setting value (32 bits) stored in the DRAM registers in the flash memory 30.

The obtaining unit 101 reads out data from the SPD memory 24. The setting unit 103 determines whether or not a value (key code) indicating that the DIMM 20 is manufactured the own company is recorded in the readout data. If the key code value is recorded, the specifying unit 102 determines which setting values are to be used for setting among the setting targets (i.e., the setting A or B in the example illustrated in FIG. 4) stored in the flash memory 30 based on the specification information, such the capacities, bus widths, and the numbers of ranks of the DIMM 20 in the SPD memory 24. Simultaneously, the setting unit 103 places setting values (MEMC_*) of the JEDEC-non-defined access parameters recorded in the SPD memory 24 in the DRAM CTL registers of the memory controller 10(1) with a higher priority than the setting values of the JEDEC-defined access parameters recorded in the flash ROM (more specifically, the DRAM registers in the flash memory 30).

The flash memory 30 corresponds to a storage unit (first storage unit) which stores multiple setting values for the DRAM 22. The multiple setting values correspond to, for example, values for the registers MEMC_1 to MEMC_* contained in the setting A and those in the setting B. The SPD memory 24 corresponds to a storage unit (second storage unit) configured to store setting values which are for the DRAM 22 and which correspond to one or more of the setting values stored in the flash memory 30.

The setting values of the JEDEC-non-defined access parameters may be either a part or all of the setting values that are to be placed in the DRAM CTL registers of the memory controller 10(1). In a case where the setting values of JEDEC-non-defined access parameters are only some of the setting values, it is difficult to cover all the setting values to be set to the memory controller 10(1) only with setting values recorded in the SPD memory 24 (JEDEC-non-defined access parameters). Accordingly, in such a case, the specifying unit 102 specifies one of the setting targets (in this example, the setting A or the setting B) of the JEDEC-defined access parameters stored in the flash memory 30 (flash ROM) based on the SPD information (specification information). The obtaining unit 101 reads out setting values of the thus-specified setting target. The setting unit 103 compares between the setting values read out from the SPD memory 24 and the setting values read out from the flash memory 30. If there is a difference between the setting values, the setting unit 103 places the setting values of the JEDEC-non-defined access parameters recorded in the SPD memory 24 in the DRAM CTL registers of the memory controller 10(1) with a higher priority.

According to the embodiment, although the setting values are recorded in the open sections in the SPD memory 24, the setting values may alternatively be recorded in other sections. The determination as to whether or not it is necessary to set the setting values stored in the SPD memory 24 may be made by a method other than the method of making the determination based on the key code indicating that the DIMM 20 is manufactured by the own company. Alternatively, for example, the determination may be made based on whether or not the SPD memory 24 contains data (JEDEC-non-defined access parameters) to be set.

To implement the applying setting values according to the embodiment, as a matter of course, it is necessary to record, in advance, setting values which can vary depending on the DRAM 22 mounted on the SPD memory 24. Examples of the setting values include a timing parameter and an ODT (on-die termination) resistance value.

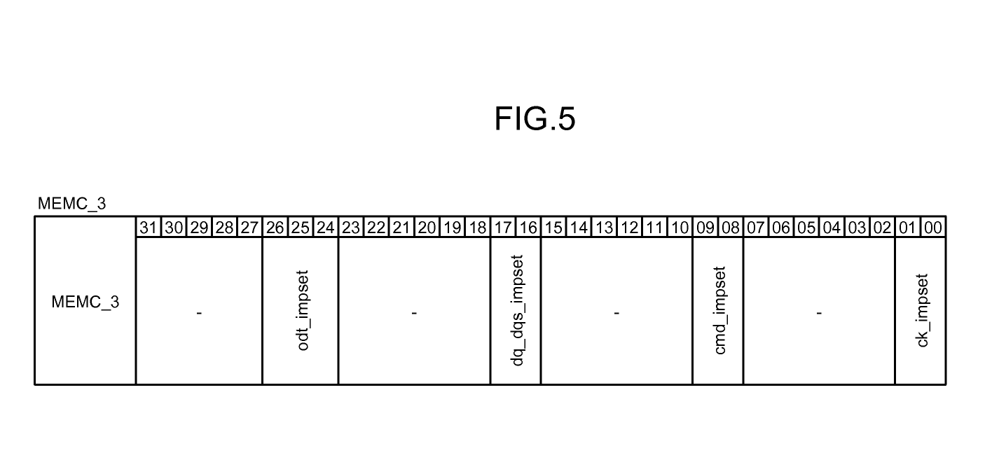

FIG. 5 is an explanatory diagram of a structure of an example of the DRAM CTL register of the memory controller 10(1).

The DRAM CTL registers of the memory controller 10(1) include, for example, the register MEMC_3. The register MEMC_3 may have the structure illustrated in FIG. 5.

More specifically, as illustrated in FIG. 5, a target value (Target) for calibration of ODT (on-die termination) impedance is placed in odt_impset on bits 26 to 24 in the DRAM CTL register. Bits 26 to 24 may encode values as follows, for example:

001b=120 Ω,

010b=60 Ω,

011b=40 Ω,

100b=34Ω, and

All others reserved.

A driver impedance for a DQ (data strobe) or a DQS (data strobe signal) is placed in dq_dqs_impset on bits 17 to 16. A macro driver impedance for a CMD (command terminal) is placed in cmd_impset on bits 09 to 08. A driver impedance for a CK (clock) is placed in ck_impset on bits 01 to 00. Bits 17 to 16, bits 09 to 08, and bits 01 to 00 may encode values as follows, for example:

00b=60 Ω,

01b=48 Ω,

10b=40Ω, and

11b=34 Ω.

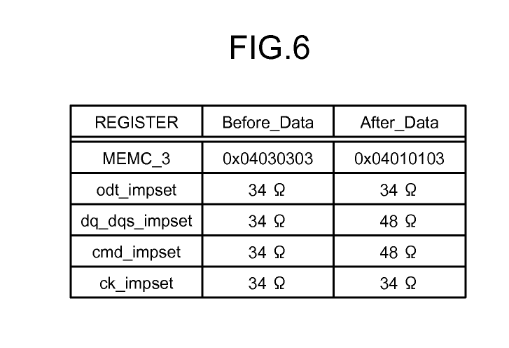

FIG. 6 is a diagram for describing there is difference in setting values to be set to the memory controller 10(1) for initialization of the main memory (the DRAM 22) between the conventional method and the method according to the embodiment.

How the setting values differ before and after (i.e., without and with) application of the embodiment described below based on the conventional method illustrated in FIG. 3 and the method according to the embodiment illustrated in FIG. 4 for configuring the DRAM 22 in the DIMM 20 by way of an example in which the setting values are placed the register MEMO_3.

Setting values of the DRAM 22 in the DIMM 20 according to the conventional method illustrated in FIG. 3 are listed in Before_Data column of FIG. 6. More specifically, a setting value in the DRAM CTL register in the memory controller 10(1) in the CPU 10 is 0x04030303 which is the setting value of the register MEMC_3 of the setting B, and. corresponding resistance values are listed in the Before_Data column of FIG. 6.

Setting values of the DRAM 22 in the DIMM 20 according to the embodiment illustrated in FIG. 4 are listed in After_Data column of FIG. 6. More specifically, a setting value is 0x04010103 which is the setting value placed in the register MEMC_3 in the memory controller 10(1) in the CPU 10. Resistance values placed in the DRAM CTL registers in the CPU 10 (the memory controller 10(1)) are listed in the After_Data column of FIG. 6.

Comparison is made between the values in the Before_Data column (hereinafter, “before data”) and the values in the After_Data column (hereinafter, “after data”). The value of odt_impset is 34Ω, which remains the same between the before data and the after data. The value of dq_dqs_impset of the before data is 34Ω, while that of the after data is 48Ω. The value of cmd_impset of the before data is 34Ω, while that of the after data is 48Ω (01b). The value of ck_impset is 34Ω, which remains the same between the before data and the after data.

In the embodiment, as described above, the setting values, such as resistance values, of the DIMM 20 are changeable using the JEDEC-non-defined access parameters recorded in the SPD memory 24.

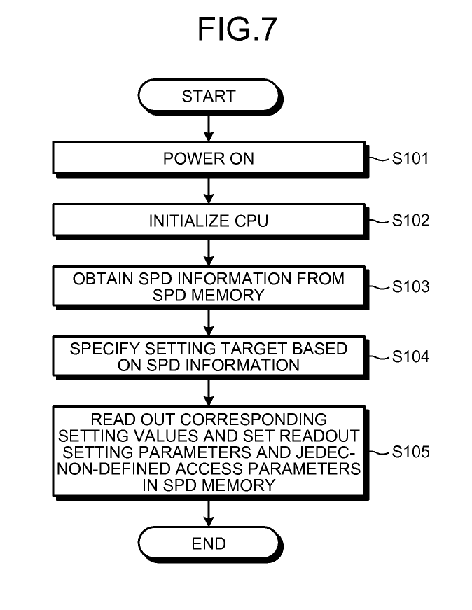

FIG. 7 is a flowchart illustrating an example sequence of operations for setting the setting values to a main memory according to the embodiment.

When power supply to the memory system 1 illustrated in FIG. 4 is switched on (S101), the CPU 10 is initialized (S102). Subsequently, the obtaining unit 101 executed by the CPU 10 obtains SPD information (specification information about the memory) from the SPD memory 24 (S103). The specifying unit 102 specifies a setting target (by selecting one of the setting A and the setting B) based on the SPD information (S104). The obtaining unit 101 reads out setting values (JEDEC-defined access parameters) of the specified setting target from the DRAM registers in the flash memory 30. The setting unit 103 sets the readout setting values (JEDEC-defined access parameters) and setting values (JEDEC-non-defined access parameters) recorded in the SPD memory 24, in the memory controller 10(1) (the DRAM CTL registers) (S105), after which the sequence ends.

As described above, if there is a difference between the setting values of the JEDEC-non-defined access parameters and the setting values of the JEDEC-defined access parameters read out by the BIOS from the DRAM registers in the flash memory 30, the setting unit 103 places the setting value of the JEDEC-non-defined access parameters with a higher priority.

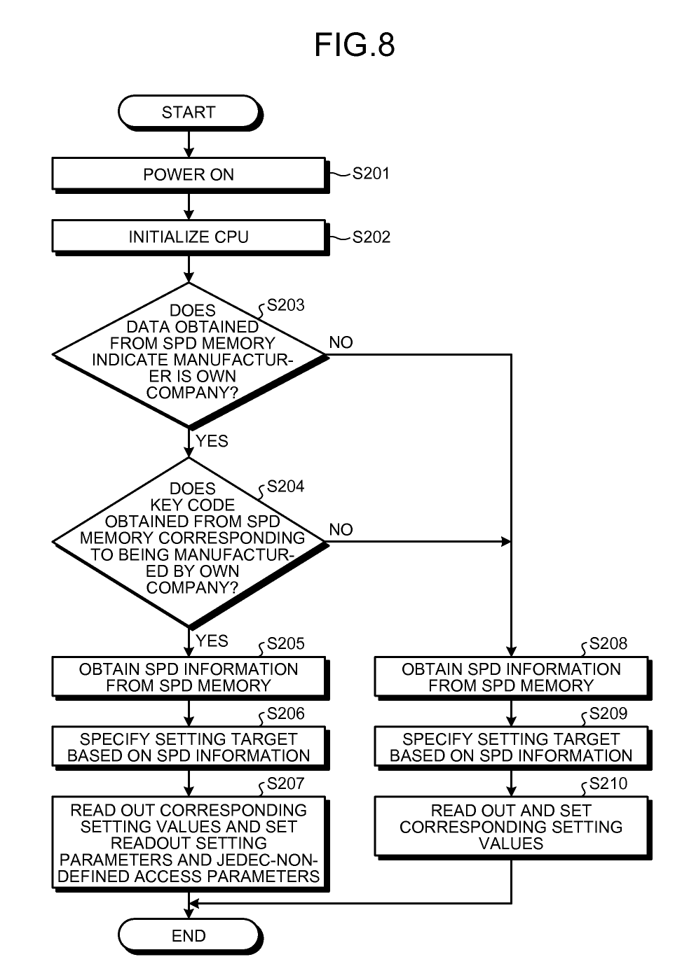

FIG. 8 is a flowchart illustrating a sequence of operations for determining whether or not it is necessary to change access parameters and, if it is determined that it is not necessary, setting default setting values which are based on JEDEC-defined access parameters obtained from the SPD memory 24.

When power supply to the memory system 1 illustrated in FIG. 4 is switched on (S201), the CPU 10 is initialized (S202). Subsequently, the setting unit 103 executed by the CPU 10 determines whether or not data obtained from the SPD memory 24 indicates being manufactured by the own company (S203). The setting unit 103 may determine whether or not the DRAM 22 is manufactured by the own company based on, for example, information identifying the manufacturer contained in the SPD information. If it is determined that it is manufactured by the own company (Yes at S203), the specifying unit 102 determines whether or not the key code value obtained from the SPD memory 24 corresponds to being manufactured by the own company (S204). If the key code value indicates being manufactured by the own company (Yes at S204), the obtaining unit 101 obtains the SPD information from the SPD memory 24 (S205). The specifying unit 102 specifies a setting target based on the obtained SPD information (S206). The obtaining unit 101 then reads out specified setting values (JEDEC-defined access parameters) from the DRAM registers in the flash memory 30. The setting unit 103 sets the readout setting values (JEDEC-defined access parameters) and setting values (JEDEC-non-defined access parameters) stored in the SPD memory 24, in the memory controller 10(1) (more specifically, in the DRAM CTL registers) (S207), after which the sequence ends.

The obtaining unit 101 obtains the SPD information (specification information) from the SPD memory 24 (S208) if the data obtained from the SPD memory 24 indicates being not manufactured by the own company (No at S203) or if the key code value obtained from the SPD memory 24 indicates that the DIMM 20 is not manufactured by the own company (No at S204). The specifying unit 102 specifies a setting target (by selecting one of the setting A and the setting B) based on the obtained SPD information (S209). The obtaining unit 101 reads out specified setting values (JEDEC-defined access parameters) from the DRAM registers in the flash memory 30. The setting unit 103 sets the readout setting values in the memory controller 10(1) (more specifically, in the DRAM CTL registers) (S210), after which the sequence then ends.

### Modification

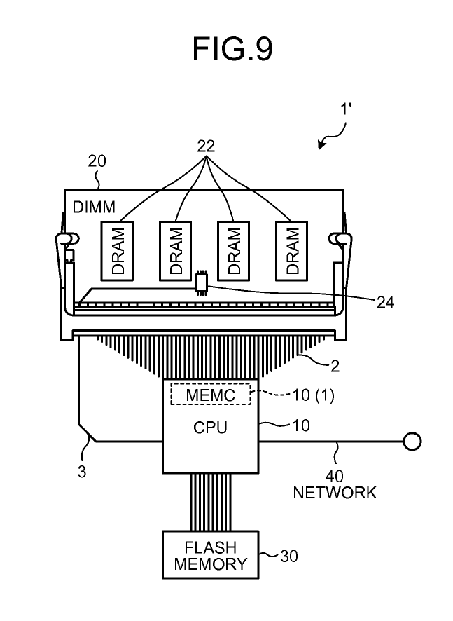

FIG. 9 is a diagram illustrating a basic structure of a memory system 1′, which is a modification of the electronic apparatus configured to initialize the main memory according to the embodiment.

The memory system 1′ according to the modification is principally identical to the memory system 1 illustrated in FIG. 1 but different in including an interface for network connection and being connected to a server (server apparatus) (not shown) over a network 40. The memory system 1′ according to the modification has a firmware updating function of obtaining firmware from the server through the interface and updating to the firmware. The network 40 can be a network based on an arbitrary protocol. Examples of the network 40 include the Internet. The network 40 may be either a wired network or a wireless network.

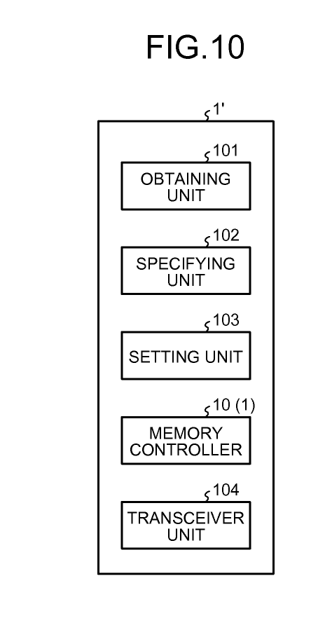

FIG. 10 is a functional block diagram illustrating an example functional structure of the electronic apparatus (memory system) according to the modification. The electronic apparatus according to the modification differs from that according to the embodiment in additionally including a transceiver unit 104. The electronic apparatus according to the modification is similar in structure and function to the electronic apparatus illustrated in FIG. 2, which is a block diagram of the electronic apparatus according to the embodiment, and repeated description is omitted.

The transceiver unit 104 transmits and receives various types of information to and from an external apparatus such as the server. For example, the transceiver unit 104 transmits specifying information specifying a printed circuit board (not shown) included in the memory system 1′ to a server, and receives access parameters transmitted from the server in response to the specifying information. The setting unit 103 stores the received access parameters in the SPD memory 24, for example. Printed circuit boards can be different in configuration from each other even when the printed circuit boards are provided by a single vendor. The specifying information is information specifying one of such printed circuit boards of different configurations.

The memory system 1′ according to the modification is configured to, in a case where a malfunction or the like occurs in the DRAM 22 which is the main memory, obtain access parameters (or, more specifically, JEDEC-non-defined access parameters) of the SPD memory 24 from the server over the network 40. The memory system 1′ according to the modification is configured to automatically update JEDEC-non-defined access parameters of the SPD memory 24 using the obtained JEDEC-non-defined access parameters.

More specifically, the CPU 10 of the electronic apparatus transmits specifying information specifying a printed circuit board (a printed circuit board including a CPU or an ASIC) based on software to the server. In response to the specifying information, the server returns JEDEC-non-defined access parameters of a corresponding DRAM. The setting unit 103 sets the JEDEC-non-defined access parameters fed from the server to the memory controller 10(1). The setting unit 103 applies the access parameters in a manner similar to that described earlier.

As described above, in the embodiment, setting values pertaining to a change of a DRAM (used as a main memory) are recorded in blank space of an SPD memory where configuration information of the DRAM is recorded. At startup, setting values recorded in the SPD memory are placed in DRAM CTL registers in a memory controller of the DRAM in a CPU or an ASIC. By using the setting values, which are JEDEC-non-defined access parameters, recorded in the SPD memory to a changed portion, even when the DRAM is shrunk multiple times, initialization of the DIMM (where the DRAM is mounted) can be performed properly.

According to the embodiment, various settings including not only settings of a waveform and timing, but also settings of a refresh period, a ZQ calibration (impedance adjustment of an external terminal) period, and the like can be set. Accordingly, the embodiment can be applied to prevent a malfunction of a specific DRAM or the like.

Embodiments and further advantages of the embodiment are described below.

(1) The setting unit determines whether or not it is necessary to change access parameters which are JEDEC-non-defined SPD information and, if it is determined that it is not necessary, sets setting values included in one of the setting targets (the setting A or the setting B) which is determined based on JEDEC-defined SPD information.

Accordingly, it is possible to cause the main memory to operate even when JEDEC-non-defined access parameters are not recorded in the SPD memory. In other words, it is possible to cause the electronic apparatus to operate irrespective of which memory module (DIMM) is included in the electronic apparatus.

(2) Because the access parameters, which are the JEDEC-non-defined SPD information, of the main memory are recorded in the SPD memory, the embodiment can be implemented with a conventional configuration. Accordingly, neither additional development nor cost for additional memory is required.
(3) The main memory and the SPD memory (the second storage unit) are on the same DIMM. Accordingly, when the DIMM is configured to be detachable, optimum parameters can be set every time the DIMM is replaced.
(4) The access parameters may be configured to be recorded in the SPD memory and another memory mounted on the DIMM as an expansion.

With this configuration, the amount of the access parameters can be increased or, in other words, in a case where the SPD memory is insufficient to store the access parameters, some of the access parameters can be stored in the expansion memory.

(5) When the electronic apparatus includes a printed circuit board (PCB) or a printed wiring board (PWB), data (access parameters) to be stored in the SPD memory can be obtained based on information identifying the manufacturer (vendor) of the printed circuit board.

When supplying the PCBs with multi-vendor (from two vendors), setting values can vary based on which one of the two vendors the PCB is supplied from. For such a case, two types of settings values may preferably be recorded in the SPD memory on a per-vendor basis. The memory system determines which one of the vendors the PCB is provided from, based on, for example, configuration pins and obtains corresponding data based on a result of the determination. This makes it possible to cope with a change other than a change of the DRAM. Accordingly, it is possible to cope with a request for multi-vendor for PCB.

(6) The electronic apparatus according to the present embodiment obtains JEDEC-non-defined access parameters containing setting information of the main memory over a network, and updates setting information with the obtained JEDEC-non-defined access parameters.

Accordingly, in a case where a malfunction or the like occurs in the DRAM 22, parameter data (the JEDEC-non-defined access parameters) in the SPD is automatically updated. At this time, the electronic apparatus transmits, for example, specifying information specifying the PCB to a server. The server returns, as a response, access parameters (JEDEC-non-defined access parameters) of the corresponding DRAM to the electronic apparatus. The PCB sets the parameters fed from the server to the memory controller. Accordingly, when it is determined that firmware of the electronic apparatus needs updating, latest firmware is automatically downloaded over the Internet, and the firmware of the electronic apparatus is automatically updated. Updating the firmware without delay leads to maintaining the apparatus in an optimum condition and, accordingly, preventing occurrence of a failure.

Because the firmware can be updated even after the electronic apparatus is introduced on the market, malfunction can be resolved easily. When the configuration which allows setting information to be updated is employed, the access parameters may be recorded in a memory (e.g., a flash memory) external to the DIMM.

The embodiment has been described by way of an example where SPD information defined by the JEDEC (put another way, compliant with the JEDEC-defined standard) and access parameters (setting values) which depend on the SPD information are used in setting of the initialization of the main memory performed when the specification of the main memory of the electronic apparatus is change. However, applicable settings are not limited to those defined by the JEDEC. More specifically, the JEDEC-defined access parameters can be any setting values (default setting values) set as default values of settings of the main memory. The JEDEC-non-defined access parameters can be any setting values based on specification information of the main memory after the specification change.

According to an embodiment, optimum settings for a mounted main memory can be set to the main memory.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electronic apparatus comprising:
a main storage unit;
a first storage unit that stores multiple pieces of first setting information for the main storage unit;
a second storage unit that stores second setting information, the second setting information being setting information for the main storage unit and corresponding to at least some of the multiple pieces of first setting information;
a setting unit that sets the second setting information with a higher priority than the first setting information; and
a control unit that controls the main storage unit based on information set by the setting unit.

2. The electronic apparatus according to claim 1, wherein the setting unit determines whether or not setting of the second setting information is necessary and, if the setting unit determines that the setting is not necessary, sets the first setting information.

3. The electronic apparatus according to claim 1, wherein the main storage unit and the second storage unit are mounted on a single memory module.

4. The electronic apparatus according to claim 1, further comprising
a printed circuit board, wherein
a second storage unit stores the second setting information corresponding to the printed circuit board.

5. The electronic apparatus according to claim 4, further comprising
a transceiver unit that transmits specifying information specifying the printed circuit board to a server apparatus and receive the second setting information transmitted from the server apparatus in response to the specifying information, wherein
the second storage unit stores the second setting information received by the transceiver unit.

6. The electronic apparatus according to claim 1, wherein
the first setting information is provided as access parameters defined by the JEDEC (Joint Electron Device Engineering Council), and
the second setting information is provided as access parameters which are not defined by the JEDEC.

7. The electronic apparatus according to claim 1, wherein
the main storage unit and the second storage unit are mounted on a single DIMM (dual inline memory module), and
the second storage unit is either an SPD (serial presence detect) storage unit storing access parameters which are not defined by the JEDEC, or a combination of the SPD storage unit and another storage unit other than the SPD storage unit.

8. A control method to be performed by an electronic apparatus including a main storage unit, a first storage unit that stores multi pieces of first setting information for the main storage unit, and a second storage unit that stores second setting information, the second setting information being setting information for the main storage unit and corresponding to at least some of the multiple pieces of first setting information, the control method comprising:
setting the second setting information with a higher priority than the first setting information; and
controlling the main storage unit based on the information set at the setting.

9. A computer program product comprising a non-transitory computer-readable medium containing an information processing program, the program, when executed by a computer including a main storage unit, a first storage unit that stores multiple pieces of first setting information for the main storage unit, and a second storage unit that stores second setting information, the second setting information being setting information for the main storage unit and corresponding to at least some of the multiple pieces of first setting information, causing the computer to function as:
a setting unit that sets the second setting information with a higher priority than the first setting information; and
a control unit that controls the main storage unit based on the information set by the setting unit.
